(19) United States
(12) Patent Application Publication
(10) Pub. No.: US 2014/0059852 A1
(43) Pub. Date: Mar. 6, 2014

(54) MULTI-LAYER PRINTED CIRCUIT BOARD COMPRISING FILM AND METHOD FOR FABRICATING THE SAME

(71) Applicant: Samsung electronics Co., Ltd., Suwon-Si (KR)

(72) Inventors: Soo-Jeoung PARK, Hwaseong-si (KR); Chul-Woo KIM, Incheon (KR); Kyoung-Sei CHOI, Yongin-si (KR); Kwang-Jin BAE, Suwon-si (KR)

(73) Assignee: SAMSUNG ELECTRONICS CO., LTD., Suwon-Si (KR)

(21) Appl. No.: 14/071,241

(22) Filed: Nov. 4, 2013

Related U.S. Application Data
(62) Division of application No. 13/032,100, filed on Feb. 22, 2011.

(30) Foreign Application Priority Data
Apr. 12, 2010 (KR) 1020100033359

(51) Int. Cl. H05K 3/46

(52) U.S. Cl. CPC H05K 3/46
USPC 29/846

(57) ABSTRACT

A multi-layer printed circuit board (PCB) and a method for fabricating the same are provided. The multi-layer printed circuit board may include a first film and a first insulation layer. The first film may include a first via therein and the first film may further include a first conductive pattern on an upper surface thereof and the first conductive layer may be electrically connected to the first via. The first insulation layer may be on the upper surface of the first film and the first insulation layer may include a second via therein and a second conductive pattern on an upper surface thereof and the second conductive pattern may be electrically connected to the second via. The second via may be electrically connected to the first conductive pattern.

### CROSS-REFERENCE TO RELATED APPLICATION

This application is a divisional of U.S. application Ser. No. 13/032,100, filed on Feb. 22, 2011, which claims priority under 35 U.S.C. §119 to Korean Patent Application No. 10-2010-0033359 filed on Apr. 12, 2010 in the Korean Intellectual Property Office (KIPO), the entire contents of each of which are herein incorporated by reference.

### BACKGROUND

1. Field

Example embodiments relate to a multi-layer printed circuit board.

2. Description of the Related Art

Along with the trends of electronic products toward miniaturization, thin profile, high-density integration, assembly into a package and high portability, a multi-layer printed circuit board (PCB) has been developed to have a relatively fine pattern and be miniaturized and packaged. In detail, in order to increase the possibility of fine pattern formation, reliability and design density of the multi-layer PCB, a raw material of the multi-layer PCB has been changed, layer constitution of the multi-layer PCB has become complicated, and components to be mounted on the multi-layer PCB have been changed from dual in-line package (DIP) types to surface mount technology (SMT) types so that an overall mount density of the components is increased. Further, since the electronic products have been developed toward high-functionality, Internet application, moving picture application and transmission/reception of high-capacity data, the PCB has required an increasingly complicated design and a high level of technology.

PCBs are divided into a single-sided PCB provided with wiring only on one surface of an insulating substrate, a double-sided PCB provided with wiring on both surfaces of an insulating substrate, and a multi-layered board (MLB) comprising multiple layers provided with wiring. Conventional electronic products had simple-structured components and a simple circuit pattern, thus mainly using the single-sided PCB. On the other hand, recent electronic products require a complicated-structured, high-density and fine circuit pattern, thus mainly using the double-sided PCB or the MLB.

Meanwhile, the multi-layer PCB has multi-layer circuit patterns, which requires to be miniaturized due to a need for increased wirings and a reduction in the relative wiring area. However, since raw materials of the conventional multi-layer PCB have limitations in realizing miniaturized multi-layer PCB, solutions to overcome the limitations are highly desired.

### SUMMARY

Example embodiments provide a multi-layer printed circuit board which can form a fine pattern.

Example embodiments also provide a method for fabricating a multi-layer printed circuit board which can form a fine pattern.

These and other objects of example embodiments will be described in or be apparent from the following description of the preferred embodiments.

In accordance with example embodiments, a multi-layer printed circuit board may include a first film and a first insulation layer. In example embodiments, the first film may include a first via therein and the first film may further include a first conductive pattern on an upper surface thereof and the first conductive layer may be electrically connected to the first via. The first insulation layer may be on the upper surface of the first film and the first insulation layer may include a second via therein and a second conductive pattern on an upper surface thereof and the second conductive pattern may be electrically connected to the second via. In example embodiments, the second via may be electrically connected to the first conductive pattern.

In accordance with example embodiments, a method for fabricating a multi-layer printed circuit board may include forming a first film having at least one of a first conductive pattern on an upper surface of the first film and a second conductive pattern on a lower surface of the first film. In example embodiments, the first film may further include a first via therein and the first via may be connected to at least one of the first conductive pattern and the second conductive pattern. In example embodiments, the method may further include forming at least one of a first insulation layer on the upper surface of the first film and a second insulation layer on the lower surface of the first film. The method may further include forming at least one of a first via hole in the first insulation layer and a second via hole in the second insulation layer. In addition, the method may further include forming at least one of a second via in the first insulation layer by forming a first plating layer on an upper surface of the first insulation layer and a third via in the second insulation layer by forming a second plating layer on a lower surface of the second insulation layer. The method may further include patterning at least one of the first and second plating layers to form an external conductive pattern.

In accordance with example embodiments, there is provided a multi-layer printed circuit board comprising a core film having a first via formed therein, an upper insulation layer formed on the core film and having a first internal conductive pattern and a second via formed therein, and an upper conductive pattern formed thereon, the upper conductive pattern electrically connected to the second via, the first internal conductive pattern electrically connected to the first via and the second via electrically connected to the first internal conductive pattern, and a lower insulation layer formed on the core film and having a second internal conductive pattern electrically connected to the first via and a third via electrically connected to the second internal conductive pattern formed therein.

In accordance with example embodiments, there is provided a multi-layer printed circuit board comprising a lower film having a first conductive pattern formed on at least one surface thereof, and a fourth via formed therein, the fourth via connected to the first conductive pattern, an insulation layer formed on the lower film and having a fifth via formed therein, the fifth via connected to the first conductive pattern, and an upper film formed on the insulation layer and having a second conductive pattern formed on at least one surface thereof, the second conductive pattern connected to the fifth via, and a sixth via formed therein, the sixth via connected to the second conductive pattern.

In accordance with example embodiments, there is provided a method for fabricating a multi-layer printed circuit board, comprising forming a core film having an internal conductive pattern formed on at least one surface thereof having a first via formed therein, the first via connected to the internal conductive pattern, forming an upper or lower insulation layer on a top surface or a bottom surface of the core film, forming a via hole in the insulation layer, forming a second via connected to the internal conductive pattern in the insulation layer and a plating layer by plating insulation layer having the via hole, and forming an external conductive pattern by patterning the plating layer.

In accordance with example embodiments, there is provided a method for fabricating a multi-layer printed circuit board, comprising preparing a lower film, an upper film and a half-cured insulator, the lower film having a first conductive pattern formed on at least one surface thereof and a fourth via formed therein, the fourth via electrically connected to the first conductive pattern, the upper film having a second conductive pattern formed on at least one surface thereof and a sixth via formed therein, the sixth via electrically connected to the second conductive pattern, forming a via hole in the insulator, filling the via hole with conductive powder, and compressing the lower film, the insulating having the via hole filled with conductive powder, and the upper film, and forming a fifth via connected to the first and second conductive patterns in the insulator.

### BRIEF DESCRIPTION OF THE DRAWINGS

The above and other features and advantages of example embodiments will become more apparent by describing in detail example embodiments thereof with reference to the attached drawings in which:

FIG. 1 is a cross-sectional view of a multi-layer printed circuit board according to example embodiments;

FIG. 2 is a cross-sectional view of a multi-layer printed circuit board according to example embodiments;

FIGS. 3 through 7 illustrate intermediate process steps in a method of fabricating the multi-layer printed circuit board shown in FIG. 1; and

FIGS. 8 through 10 illustrate intermediate process steps in a method of fabricating the multi-layer printed circuit board shown in FIG. 2.

### DETAILED DESCRIPTION OF EXAMPLE EMBODIMENTS

Advantages and features of example embodiments and methods of accomplishing the same may be understood more readily by reference to the following detailed description of example embodiments and the accompanying drawings. The present invention may, however, be embodied in many different forms and should not be construed as being limited to example embodiments set forth herein. Rather, example embodiments are provided so that this disclosure will be thorough and complete and will fully convey the concepts of the invention to those skilled in the art, and the present invention will only be defined by the appended claims. In the drawings, the size and relative sizes of layers and regions may be exaggerated for clarity.

Like numbers refer to like elements throughout. As used herein, the term “and/or” includes any and all combinations of one or more of the associated listed items.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “made of,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of example embodiments.

Example embodiments are described herein with reference to cross section illustrations that are schematic illustrations of idealized example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

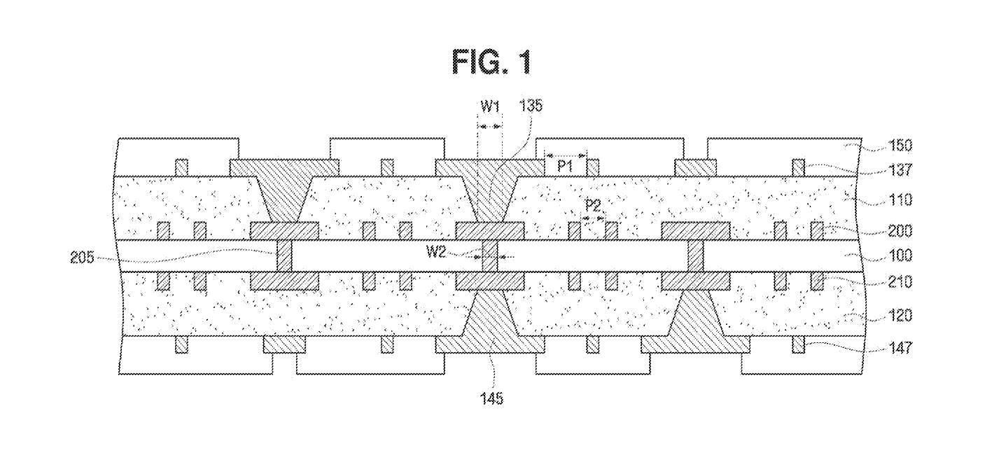

Hereinafter, a multi-layer printed circuit board (PCB) according to example embodiments will be described with reference to FIG. 1.

FIG. 1 is a cross-sectional view of a multi-layer printed circuit board (PCB) according to example embodiments. Unlike the concept ‘layer’ commonly understood by one of ordinary skill in the related art, the term ‘film’ used throughout the specification refers to an independent unit that has its own ductility and is independently manufactured.

Referring to FIG. 1, the multi-layer PCB may include a core film 100, an upper insulation layer 110, and a lower insulation layer 120. The core film 100 may be an independent unit that has its own ductility and is independently manufactured. In example embodiments, a first via 205 (or a plurality thereof) may be formed in the core film 100. The core film 100 may be, for example, a polyimide (PI) film or a liquid crystal polymer (LCP) film, but example embodiments are not limited thereto.

In example embodiments, the upper insulation layer 110 may be formed on a top surface of the core film 100. For example, the upper insulation layer 110 may be entirely formed on the top surface of the core film 100. The upper insulation layer 110 may include a first internal conductive pattern 200 and a second via 135 electrically connected to the first internal conductive pattern 200. In example embodiments, the first internal conductive pattern 200 may be formed on the core film 100 and the upper insulation layer 110 may cover a first internal conductive pattern 200 that is on the core film 100. In this latter example, a second via 135 may be formed in the upper insulation layer 110 to connect to the first internal conductive pattern 200. In example embodiments, the first internal conductive pattern 200 may be electrically connected to the first via 205. The upper insulation layer 110 may further include an upper conductive pattern 137 on the upper insulation layer 110 and the upper conductive pattern 137 may be electrically connected to the second via 135. As shown in FIG. 1, a top surface of the upper conductive pattern 137 may be covered by a passivation layer 150, except for a mounting region, as shown in FIG. 1.

The upper insulation layer 110 may be formed of, for example, a prepreg (PPG) or an LCP, but example embodiments are not limited thereto.

In example embodiments, a lower insulation layer 120 may be formed on a bottom surface of the core film 100. As shown in FIG. 1, the lower insulation layer 120 may also be entirely formed on the bottom surface of the core film 100. A second internal conductive pattern 210 electrically connected to the first via 205 and a third via 145 may be formed in the lower insulation layer 120, and a lower conductive pattern 147 electrically connected to the third via 145 may additionally be formed on a bottom surface of the lower insulation layer 120. In example embodiments, a bottom surface of the lower conductive pattern 147 may also be covered by the passivation layer 150, except for a mounting region, as shown in FIG. 1.

The lower insulation layer 120 may also be formed of a prepreg (PPG) or an LCP, but example embodiments are not limited thereto.

In the multi-layer PCB according to example embodiments, as shown in FIG. 1, since the core layer is formed as the core film 100, the overall thickness of the multi-layer PCB can be reduced, compared to a case where the core layer is formed as an insulation layer made of a half-cured resin. In addition, the minimum pitch P2 of the first internal conductive pattern 200 or the second internal conductive pattern 210 may be smaller than the minimum pitch P1 of the upper conductive pattern 137 or the lower conductive pattern 147. Further, a width W2 of the first via 205 may be smaller than a width W1 of the second via 135 or the third via 145.

For these reasons, the multi-layer PCB shown in FIG. 1 can easily form an internal fine pattern, which increases a degree of freedom in the circuit design, thereby enabling the manufacture of a multi-layer PCB having more complex circuit patterns.

Described differently, FIG. 1 discloses an example of a multi-layer printed circuit board having at least a first film 100 (the core film) with a first via 205. The multi-layer printed circuit board also includes a first insulation layer 110 on an upper surface of the first film 100, the first insulation layer 110 having a first conductive pattern 200 at a lower face of the first insulation layer 110, a second via 135 therein, and a second conductive pattern 137 at an upper face of the first insulation layer 110. In example embodiments, the second conductive pattern 137 may be electrically connected to the second via 135, the first conductive pattern 200 may be electrically connected to the first via 205, and the second via 135 may be electrically connected to the first conductive pattern 200.

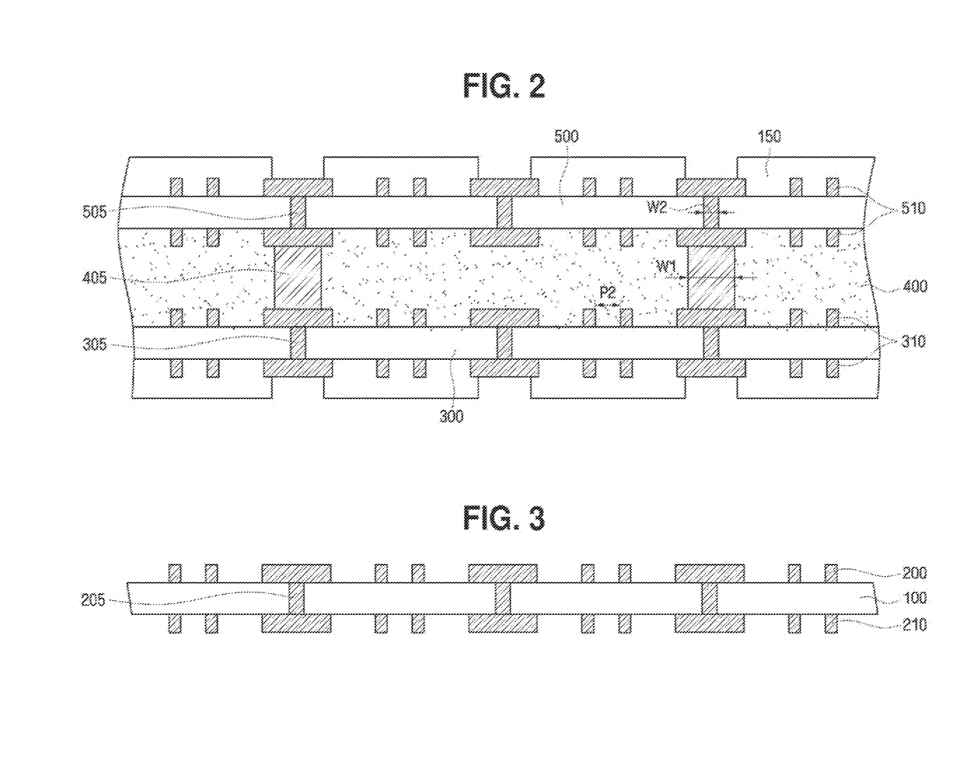

FIG. 2 is a cross-sectional view of a multi-layer printed circuit board (PCB) according to example embodiments.

Referring to FIG. 2, the multi-layer PCB may include a lower film 300, an insulation layer 400, and an upper film 500. As described above, each of the lower film 300 and the upper film 500 may be an independent unit having its own ductility and can be independently manufactured.

The lower film 300 may include a first conductive pattern 310 formed on surfaces thereof and a fourth via 305 electrically connected to the first conductive pattern 310 formed therein. Although FIG. 2 illustrates the first conductive pattern 310 on both top and bottom surfaces of the lower film 300, any one of the first conductive pattern 310 formed on either or both surfaces may be omitted, if necessary.

The passivation layer 150 may be formed on a bottom surface of the lower film 300, except for a mounting region, as shown in FIG. 2. The lower film 300 may be a polyimide (PI) film, a liquid crystal polymer (LCP) film, but example embodiments are not limited thereto.

An insulation layer 400 may be formed on a top surface the lower film 300. As shown in FIG. 2, the insulation layer 400 may be entirely formed on the top surface of the lower film 300, and a fifth via 405 electrically connected to the first conductive pattern 310 may be formed in the insulation layer 400. The insulation layer 400 may be formed of, for example, a prepreg (PPG) or an LCP, but example embodiments are not limited thereto.

The upper film 500 may include a second conductive pattern 510 formed on at least one surface thereof and a sixth via 505 electrically connected to the second conductive pattern 510 formed therein. Although FIG. 2 illustrates the second conductive pattern 510 on both of top and bottom surfaces of the upper film 500, any one of the second conductive pattern 510 formed on both surfaces may be omitted, if necessary.

Like the lower film 300, a passivation layer 150 may also be formed on the upper film 500, except for a mounting region, as shown in FIG. 2. The upper film 500 may be a polyimide (PI) film, a liquid crystal polymer (LCP) film, but example embodiments are not limited thereto.

In the the multi-layer PCB according to example embodiments, as shown in FIG. 2, since both external layers are formed in forms of films, that is, the lower film 300 and the upper film 500, the overall thickness of the multi-layer PCB can be reduced, compared to a case where the external layers are both formed as insulation layers made of a half-cured resin. In addition, a width W2 of the fourth via 305 or the sixth via 505 may be smaller than a width W1 of the fifth via 405.

For these reasons, the multi-layer PCB shown in FIG. 2 can easily form an external fine pattern, which may increase a degree of freedom in the circuit design, thereby manufacturing a multi-layer PCB having more complex circuit patterns.

Described differently, FIG. 2 discloses an example of a multi-layer printed circuit board having at least a first film 300 with a first via 305. The multi-layer printed circuit board also includes a first insulation layer 400 on an upper surface of the first film 300, the first insulation layer 400 having a first conductive pattern 310 at a lower face of the first insulation layer 400, a second via 405 therein, and a second conductive pattern 510 at an upper face of the first insulation layer 400. In example embodiments, the second conductive pattern 510 may be electrically connected to the second via 405, the first conductive pattern 310 may be electrically connected to the first via 305, and the second via 405 may be electrically connected to the first conductive pattern 310.

FIGS. 3 through 7 illustrate intermediate process steps in a method of fabricating the multi-layer printed circuit board shown in FIG. 1. Hereinafter, detailed descriptions of repeated content described in example embodiments above (for example, materials of the same or corresponding elements) will not be given.

First, a core film may be formed, the core film may have an internal conductive pattern formed on at least one surface thereof and a first via electrically connected to the internal conductive pattern formed thereon. Specifically, in FIG. 3, a core film 100 may be formed, the core film 100 may have a first internal conductive pattern 200 on its top surface, a second internal conductive pattern 210 formed on its bottom surface, and a first via 205 electrically connected to the first internal conductive pattern 200 and the second internal conductive pattern 210. The core film 100 may be formed by a roll to roll method.

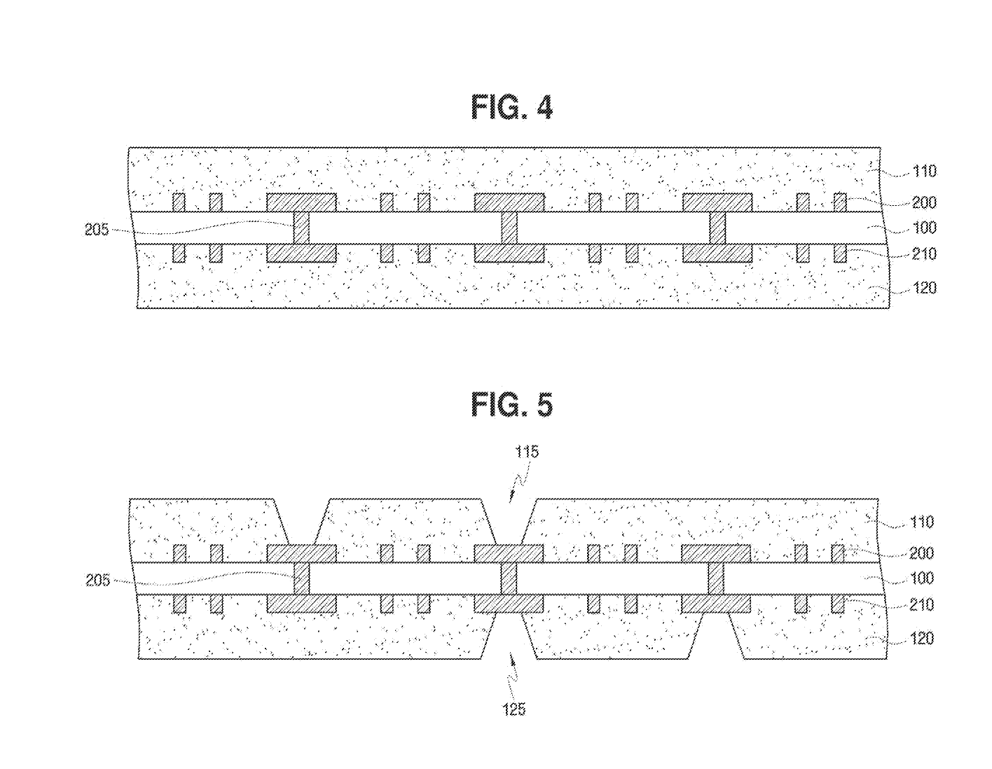

In example embodiments, an insulation layer may be formed on either a top surface or a bottom surface of the core film 100. Specifically, as shown in FIG. 4, an upper insulation layer 110 may be formed on the top surface of the core film 100, and a lower insulation layer 120 may be formed on the bottom surface of the core film 100. In example embodiments, the upper insulation layer 110 and the lower insulation layer 120 may be entirely formed on the top and bottom surfaces of the core film 100. In example embodiments, in order to increase adhesion between the core film 100 and each of the upper and lower insulation layers 110 and 120, plasma treatment may be performed on a surface of the core film 100 prior to formation of the upper and lower insulation layers 110 and 120.

In example embodiments, a via hole may be formed in the insulation layer. Specifically, as shown in FIG. 5, via holes 115 and 125 may be optionally formed by performing laser drilling on the upper insulation layer 110 and the lower insulation layer 120. In example embodiments, the via holes 115 and 125 may be formed such that at least portions of the first internal conductive pattern 200 and the second internal conductive pattern 210 are exposed.

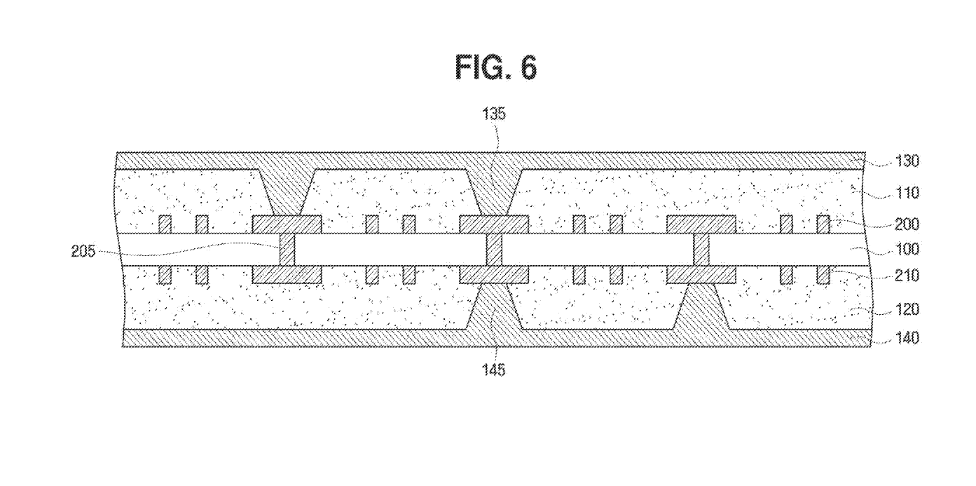

As described above, the insulation layer may have a via hole formed therein. In example embodiments, the via hole may be subject to a plating operation for form a via. For example, a via hole may be formed in an insulation layer to expose an internal conductive pattern and a second via may be formed to electrically connect to the internal conductive pattern by forming a plating layer on the insulation layer in a manner that at least partially, if not completely, fills the via hole. More specifically, as shown in FIG. 6, an upper plating layer 130 may deposited on the upper insulation layer 110 to fill the via hole 115 (see FIG. 5) to form a second via 135 electrically connected to the first internal conductive pattern 200 in the upper insulation layer 110. Additionally (or alternatively), the lower insulation layer 120 having the via hole 125 may be plated with a plating material to form a lower plating layer 140. The plating material may at least partially fill (or completely fill) the via hole 125, thereby forming a third via 145 electrically connected to the second internal conductive pattern 210 in the lower insulation layer 120.

Although example embodiments illustrate forming the second and third vias 135 and 145 by a plating operation, example embodiments are not limited thereto. For example, the vias 115 and 125 may be filled with a conductive material by an operation different from a plating operation. For example, a mask may he applied over the upper and lower insulation layers 110 and 120 with holes in the mask exposing the vias 115 and 125. A filling operation may then be performed to fill the vias 115 and 125 with a conductive material to form the second and third vias 135 and 145. Subsequently, a plating operation may be performed to cover the second and third vias 135 and 145 and the first and second insulation layers 110 and 120 to form the upper and lower plating layers 130 and 140.

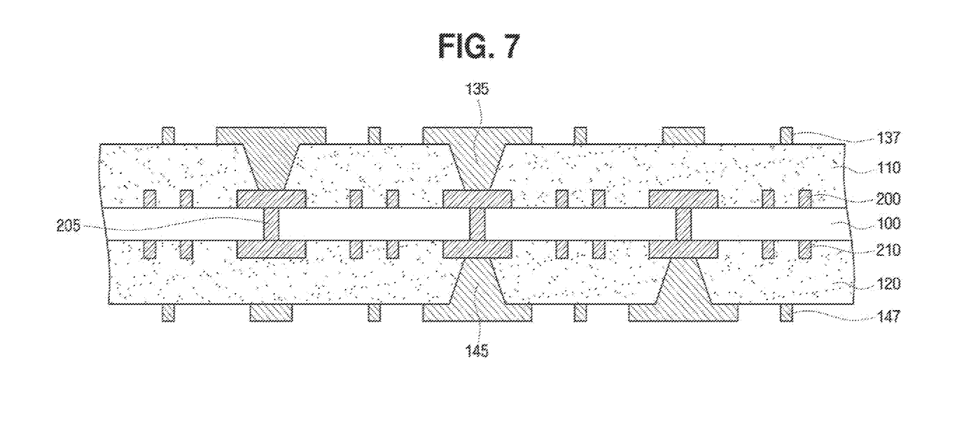

In example embodiments, the plating layer may be patterned, thereby forming an external conductive pattern. For example, as shown in FIG. 7, the upper plating layer 130 may be patterned, thereby forming an upper conductive pattern 137, and the lower plating layer 140 may be patterned, thereby forming a lower conductive pattern 147.

In example embodiments, a passivation layer 150 may be formed on the upper conductive pattern 137 and the lower conductive pattern 147, except for a mounting region, thereby forming the multi-layer PCB shown in FIG. 1.

As described above, in the method of fabricating the multi-layer PCB according to example embodiments, since the existing process of forming a core layer in the form of an insulating layer made of a half cured resin can be utilized without any additional step, a core layer in the form of a film can be manufactured, thereby enabling the manufacture of the multi-layer PCB in a cost-efficient manner.

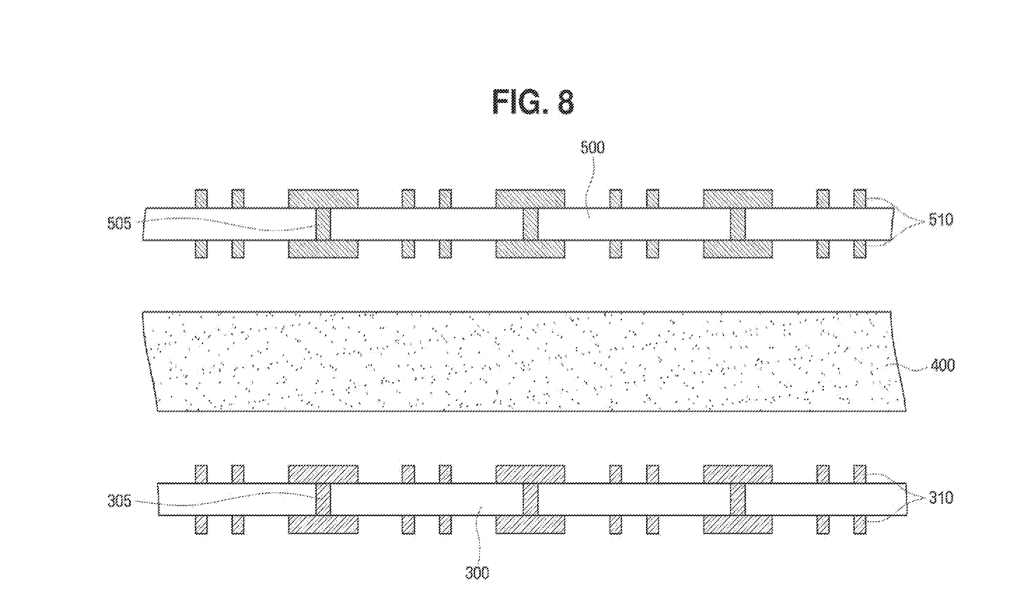

FIGS. 8 through 10 illustrate intermediate process steps in a method of fabricating the multi-layer printed circuit board shown in FIG. 2. Hereinafter, detailed descriptions of repeated content described in example embodiments above (for example, materials of the same or corresponding elements) will not be given.

In example embodiments, a lower film, an upper film, and an insulator, may be prepared. The lower film may have a first conductive pattern formed on at least one surface thereof and a fourth via formed therein. The fourth via may be electrically connected to the first conductive pattern. The upper film may have a second conductive pattern formed on at least one surface thereof and a sixth via formed therein. The sixth via may be electrically connected to the second conductive pattern. In example embodiments, the insulator may be half-cured. Specifically, as shown in FIG. 8, a lower film 300, an upper film 500 and an insulator 400 may be prepared. The lower film 300 may have a first conductive pattern 310 formed on top and bottom surfaces thereof, and a fourth via 305 electrically connected to the first conductive pattern 310 formed therein. The upper film 500 may have a second conductive pattern 510 formed on top and bottom surfaces thereof and a sixth via 305 electrically connected to the first conductive pattern 310 formed therein. In FIG. 8, the insulator 400 may be in a semi-cured B stage. As described above, although FIG. 8 illustrates the lower film 300 and the upper film 500 as having their respective conductive patterns on both of top and bottom surfaces thereof, the conductive pattern formed on any one surface of both may be omitted, if necessary.

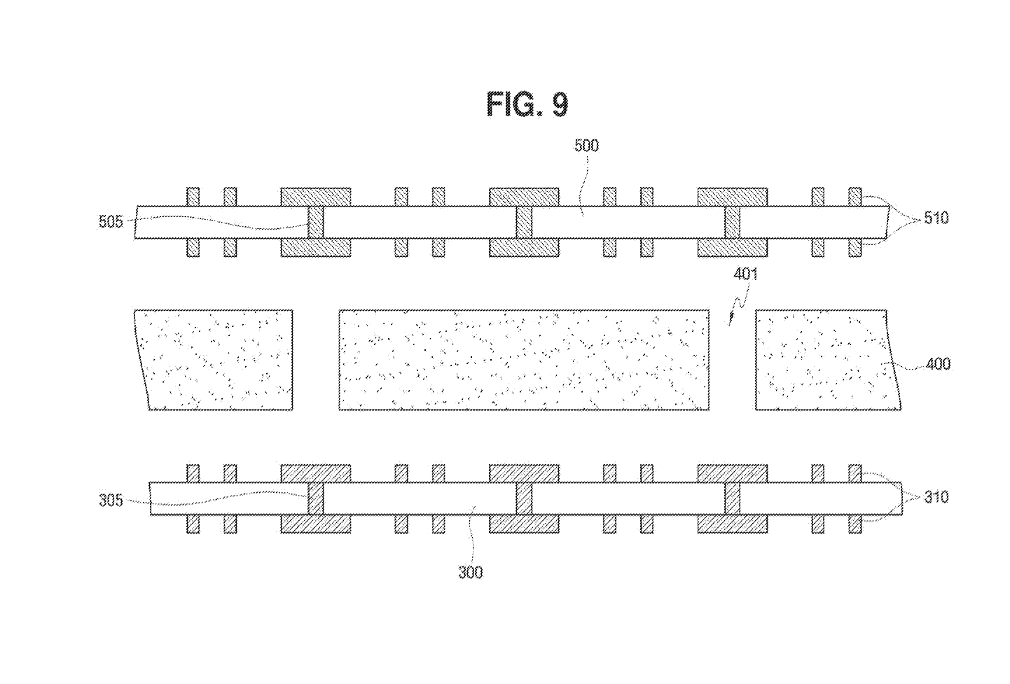

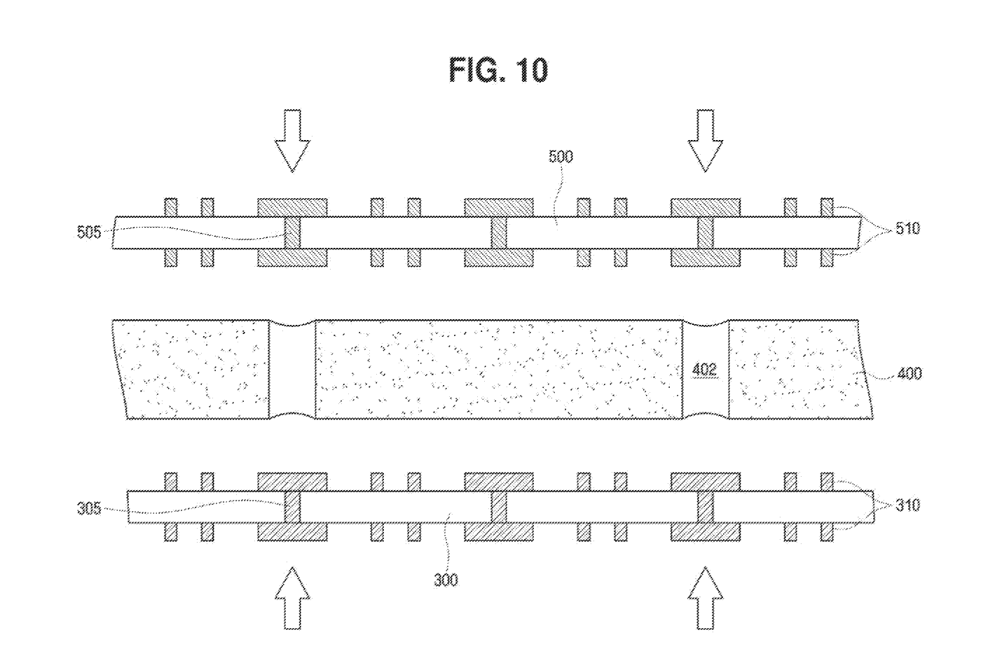

In example embodiments, a via hole may be formed in the insulator (see, for example, the via hole 401 of FIG. 9 formed in the insulator 400). In example embodiments, the via hole may be filled with a conductive powder and the lower film, the insulator having the via hole filled with conductive powder, and the upper film may be compressed against each other to form a fifth via electrically connected the first and second conductive patterns in the insulator. Specifically, as shown in FIG. 10, the via hole 401 formed in the insulator may be filled with conductive powder 402 and the lower film 300, the insulator 400, and the upper film 500 are compressed in a direction indicated by arrows, thereby forming the fifth via 405 electrically connected the first and second conductive patterns 310 and 510 in the insulator 400. Here, a problem associated with alignment of the lower film 300, the insulator 400, and the upper film 500 can be solved by forming holes in the films 300 and 500.

As described above, in the method of fabricating the multi-layer PCB according to example embodiments, the multi-layer PCB which can form an external fine pattern through a simplified process can be achieved.

While example embodiments have been particularly shown and described, it will be understood by those of ordinary skill in the art that various changes in form and details may be made therein without departing from the spirit and scope of example embodiments as defined by the following claims. It is therefore desired that example embodiments be considered in all respects as illustrative and not restrictive, reference being made to the appended claims rather than the foregoing description to indicate the scope of the invention.

1.-12. (canceled)

13. A method for fabricating a multi-layer printed circuit board, comprising:
forming a first film using a roll to roll method, the first film having at least one of a first conductive pattern on an upper surface of the first film and a second conductive pattern on a lower surface of the first film, the first film further including a first via therein, the first via connected to at least one of the first conductive pattern and the second conductive pattern;
forming at least one of a first insulation layer on the upper surface of the first film and a second insulation layer on the lower surface of the first film;
forming at least one of a first via hole in the first insulation layer and a second via hole in the second insulation layer;
forming at least one of a second via in the first insulation layer by forming a first plating layer on an upper surface of the first insulation layer and a third via in the second insulation layer by forming a second plating layer on a lower surface of the second insulation layer; and
patterning at least one of the first and second plating layers to form an external conductive pattern.

14. (canceled)

15. The method of claim 13, further comprising:
performing plasma treatment on the first film after forming the first film.

16. The method of claim 13, wherein forming one of the first and second insulation layers includes one of forming the first insulation layer entirely on the upper surface of the first film and forming the second insulation layer entirely on the lower surface of the first film.

17. The method of claim 13, wherein forming at least one of the first via hole in the first insulation layer and the second via hole in the second insulation layer includes at least one of forming the first via hole in the first insulation layer so as to at least partially expose the first conductive pattern and forming the second via hole in the second insulation layer so as to at least partially expose the second conductive pattern.

18. The method of claim 17, wherein the first plating layer at least partially contacts the first conductive pattern and the second plating layer at least partially contacts the second conductive pattern.

19. The method of claim 17, further comprising:
forming a second film on the first insulation layer, wherein the first insulation layer includes the first via hole and the second via and the second via is aimed by filling the first via hole with conductive powder and compressing the first film, the first insulation layer having the via hole filled with conductive powder, and the second film.

20. The method of claim 19, wherein at least one of the first film and the second film include at least one of a polyimide (PI) film and a liquid crystal polymer (LCP) film.
